(19) United States
(12) Patent Application Publication
(10) Pub. No.: US 2006/0176948 A1
(43) Pub. Date: Aug. 10, 2006

(54) Decision-feedback channel equalizer usable with a digital receiver and method thereof

(76) Inventor: Dong-hoon Lee, Suwon-si (KR)

Correspondence Address: STANZIONE & KIM, LLP, 919 18TH STREET, N.W., SUITE 440, WASHINGTON, DC, 20006, US

(21) Appl. No.: 11/320,796

(22) Filed: Dec. 30, 2005

(30) Foreign Application Priority Data
Feb. 4, 2005 (KR) 2005-10671

(51) Int. Cl. H03H 7/30; H04B 1/10

(52) U.S. Cl. 375/233; 375/350

(57) ABSTRACT

A decision feedback channel equalizer of a digital receiver includes a feedforward filter to receive and filter a demodulated signal to remove one or more ghost signals, a hard decision unit to decide a decision value based on a first signal outputted from the feedforward filter, a feedback filter to receive and filter the decision value, and to output a second signal, and a hard decision error estimator to estimate a hard decision error rate based on the demodulated signal, the first signal and the decision value, and to control the equalizer to update tap coefficients of the feedforward filter and the feedback filter according to the hard decision error rate. Accordingly, the tap coefficients of the feedforward filter and the feedback filter may be adjusted adaptively based on the hard decision error rate.

### CROSS-REFERENCE TO RELATED APPLICATIONS

This application claims benefit under 35 U.S.C. §119 from Korean Patent Application No. 2005-10671 filed on Feb. 4, 2005 in the Korean Intellectual Property Office, the entire disclosure of which is incorporated herein by reference.

### BACKGROUND OF THE INVENTION

1. Field of the Invention

The present general inventive concept relates in general to a decision-feedback channel equalizer usable with a digital receiver and a method thereof. More specifically, the present general inventive concept relates to a decision-feedback channel equalizer capable of estimating an error rate per decision and adaptively adjusting a filter tap coefficient according to the estimated error rate, and a method thereof.

2. Description of the Related Art

A digital broadcast system that uses a VSB (Vestigial Side Band) is a single carrier system having a simple hardware configuration for data processing, but a short signal interval associated with the digital broadcast system often increases a symbol error rate.

Also, when a signal from a digital broadcast transmitter of the digital broadcast system passes through a transmission channel, it is easily distorted. This signal distortion is caused by Gaussian noise, fading, changes in frequency and so forth. Unlike a conventional analog broadcast, the digital broadcast system is susceptible to beat detection errors which can cause serious damage to data reconstitution.

Examples of errors that occur in the digital broadcast system are time delays in signal transmission which are often observed in a poor channel environment and multi-channels. The time delays are due to a phase change that easily generates ISI (InterSymbol Interference), and creates ghost signals or noises besides original signals. In a worse case, the time delays become main causes of beat detection errors, and can prevent the effective use of a frequency band and the enhancement of signal receiving capabilities.

In an effort to solve the above-described problem, the digital broadcast receiver of the digital broadcast system utilizes an equalizer for removing ghost signals generated in an abnormal transmission channel and compensating for signal distortion, so that the beat detection errors can be reduced and original signals can be restored as desired.

Examples of the equalizer include a traditional equalizer composed of feedforward filters only, and a decision feedback equalizer having a feedback filter that uses hard decision directed output signals. Particularly, the decision feedback equalizer is widely used in broadcast and communication systems including a VSB digital broadcasting receiver because it can control noise enhancement generated in different channel environments, and is equipped with superior equalization capabilities compared with the traditional equalizer composed of feedforward filters only.

FIGS. 1 and 2 are schematic block diagrams of a conventional decision feedback channel equalizer.

Referring to FIGS. 1 and 2, the decision feedback channel equalizer includes a feedforward filter 10, a first subtracter 20, a symbol decision unit 30, a second subtracter 40, and a feedback filter 50.

Although, the decision feedback channel equalizers in both FIGS. 1 and 2 have the same constitutional elements, they are slightly different in that span areas of the feedforward filter 10 and the feedback filter 50 in FIG. 2 are overlapped with each other. The decision feedback channel equalizer in a VSB digital broadcasting receiver receives a demodulated signal from a demodulator (not shown), and removes ghost signals generated in a poorly conditioned channel and compensates for channel distortion to generate a restored signal. The restored signal is then input to a decoder (not shown).

Meanwhile, there are several factors that influence a channel environment statically and dynamically, such as, a position of a transceiver, geographical features of an area where the transceiver stands, buildings, etc. In order to respond more adaptively to these channel status changes, a tap coefficient of an equalizer filter is updated periodically, so that linear distortions in a channel can be equalized and the channel distortions, i.e., inter-symbol interference (ISI), can be removed.

A typically used adaptive algorithm for tap coefficient updates of the decision feedback channel equalizer is the Least Mean Square (LMS) algorithm.

Equations 1 and 2 below illustrate filter coefficient update equations based on the LSM algorithm.
W_{f}(n+1)=W_{f}(n)+μ_{f}r(n)e*(n) [Equation 1]
where “W_{f}(n),” “r(n)” and “μ_{f}” indicate a tap coefficient vector, received signal vector, and step size of a feedforward filter, respectively, and “e*(n)” indicates an error signal.
W_{b}(n+1)=W_{b}(n)+μ_{b}y′(n)e*(n) [Equation 2]
where “W_{b}(n),” “y′(n)”, and “μ_{b}” indicate a tap coefficient vector, hard decision data vector, and step size of a feedback filter, respectively, and “e*(n)” indicates an error signal.

Despite many advantages of the decision feedback channel equalizer, the decision error rate is still very high in a poorly conditioned channel environment where strong ghost signals exist. This leads to an error propagation problem, and deteriorations in performance of the equalizer.

In other words, in an environment having the strong ghost signals, the tap coefficient of the feedback filter is unfortunately very high. Thus, when a decision error is generated, the possibility of error propagation is increased as well.

As an attempt to resolve this phenomenon, a leaky LMS algorithm has been used or span areas of the feedforward filter 10 and the feedback filter 50 have been overlapped, as illustrated in FIG. 2.

Using the leaky LSM algorithm to update the tap coefficient of the feedback filter 50, the Equation 2 is slightly transformed (or modified) to obtain Equation 3 as follows.
W_{b}(n+1)=(1−α_{b}μ_{b})W_{b}(n)+μ_{b}y′(n)e*(n) [Equation 3]
where “α_{b}μ_{b}” indicates a leaky factor of the feedback filter, and satisfies the condition of “0≦α_{b}μ_{b}≦1.”

According to the leaky LMS algorithm illustrated in Equation 3, the leaky factor is inversely proportional to the tap coefficient of the feedback filter. Therefore, the possibility of error propagation due to the decision error is lowered.

On the other hand, the purpose of the filter overlapping method illustrated in FIG. 2 is to split the responsibility for removing the strong ghost signals between the feedforward filter and the feedback filter. Similar to the leaky LMS algorithm, this method is also advantageous for decreasing the tap coefficient of the feedback filter and the possibility of error propagation.

In addition, by having the feedforward filter remove the ghost signals that the feedback filter could not remove, the equalization capabilities of the equalizer can be enhanced.

In effect, the leaky LMS algorithm can also be applied to the overlapped structure illustrated in FIG. 2 for the tap coefficient update of the feedforward filter. To this end, Equation 1 is transformed (or modified) to Equation 4 as follows.
W_{f}(n+1)=(1−α_{f}μ_{f})W_{f}(n)+μ_{f}r(n)e*(n) [Equation 4]
where “α_{f}μ_{f}” indicates a leaky factor of the feedforward filter, and satisfies the condition of “0≦α_{f}μ_{f}≦1.”

Although the leaky LMS algorithm can successfully limit the tap coefficient of the feedback filter and reduce the possibility of error propagation, it has side effects in that the ghost signal removing capabilities are deteriorated and an output SNR (Signal-to-Noise Ratio) of the equalizer is reduced.

Moreover, according to the leaky LMS algorithm, an optimum leaky factor is different by channel environments, so it is very difficult to set an adequate value.

This same problem of the leaky LMS algorithm is also found in the overlapped structure illustrated in FIG. 2. That is, not only the feedforward filter limits the ghost signal removing capabilities of the feedback filter, but also the noise enhancement caused by the feedforward filter often lowering the output SNR compared to that of an ideal DFE (decision feedback equalizer).

### SUMMARY OF THE INVENTION

The present general inventive concept provides a decision feedback channel equalizer usable with a digital receiver to adaptively adjust a leaky factor or tap coefficient of a feedforward filter and a feedback filter by estimating the error rate of a hard decision unit to reduce a symbol error rate, and a method thereof.

Additional aspects and advantages of the present general inventive concept will be set forth in part in the description which follows and, in part, will be obvious from the description, or may be learned by practice of the general inventive concept.

The foregoing and/or other aspects of the present general inventive concept may be achieved by providing a decision feedback channel equalizer to demodulate and equalize a signal in a digital receiver, the equalizer including a feedforward filter to receive and filter a demodulated signal to remove one or more ghost signals from the demodulated signal, a hard decision unit to decide a decision value based on a first signal output from the feedforward filter a feedback filter to receive and filter the decision value, and to output a second signal, and a hard decision error estimator to estimate a hard decision error rate based on the demodulated signal, the first signal and the decision value being received, and to control the feedforward filter and the feedback filter to update tap coefficients of the feedforward filter and the feedback filter according to the hard decision error rate.

If the error rate estimated by the hard decision error estimator is low, the hard decision error estimator may update the tap coefficient of the feedforward filter to limit a ghost signal removing capability of the feedforward filter.

If the error rate estimated by the hard decision error estimator is high, the hard decision error estimator may update the tap coefficient of the feedback filter to limit ghost signal removing capabilities of the feedback filter.

The hard decision error estimator may update the tap coefficient of the feedforward filter by applying the following equation:
W_{f}(n+1)=[1−Γ_{f}(μ_{f}·β_{f}(r(n),y_{f}(n),y′(n)))]W_{f}(n)+μ_{f}r(n)e*(n)
where “Γ_{f}(μ_{f}·β_{f}(r(n),y_{f}(n),y′(n)))” is a feedforward leaky factor, having a value in a range from 0 to 1, “W_{f}(n),” “r(n)” and “μ_{f}” indicate a tap coefficient vector, demodulated signal vector, and step size of a feedforward filter, respectively, and “e*(n)” indicates an error signal.

The feedforward leaky factor of the feedforward filter may be calculated by the following equation:
Γ_{f}(μ_{f}·β_{f}(r(n),y_{f}(n),y′(n)))=Γ_{f}(μ_{f}·K_{f}·E{y_{f}(n)y′*(n)})
where “K_{f}” is a random positive real number.

The hard decision error estimator may update the tap coefficient of the feedback filter by applying the following equation:
W_{b}(n+1)=[1−Γ_{b}(μ_{b}·β_{b}(r(n),y_{f}(n),y′(n)))]W_{b}(n)+μ_{b}r(n)e*(n)
where “Γ_{b}(μ_{b}·β_{b}(r(n),y_{f}(n),y′(n)))” is a feedback leaky factor, having a value in a range from 0 to 1, “W_{b}(n),” “r(n)” and ”μ_{b}” indicate a tap coefficient vector, demodulated signal vector, and step size of a feedback filter, respectively, and “e*(n)” indicates an error signal.

The feedback leaky factor of the feedback filter may be calculated by the following equation:
Γ_{b}(μ_{b}·β_{b}(r(n),y_{f}(n),y′(n)))=Γ_{b}(μ_{b}·K_{b}·E|y_{f}(n)−y′(n)|ⁿ)
where “K_{b}” is a random positive real number.

Also, the hard decision error estimator may use at least one of E|r(n)−y′(n)|ⁿ, E{r(n)y′*(n)}, E|y_{f}(n)−y′(n)|ⁿ, and E{y_{f}(n)y′*(n)} values to estimate the hard decision error rate, when “r(n),” “y_{f}(n)” and “y′(n)” indicate the demodulated input signal, the first signal and the decision value, respectively.

The decision feedback channel equalizer may further include a first subtracter to perform a first subtraction operation on the first and the second signals received from the feedforward filter and the feedback filter, respectively, and to calculate a first subtraction value from the first subtraction operation.

The decision feedback channel equalizer may further include a second subtracter to perform a second subtraction operation by subtracting the first subtraction value received from the first subtracter and the decision value received from the hard decision unit, respectively, to generate an second subtraction value from the second subtraction operation, and to provide the generated second subtraction value to the feedback filter to output the second signal.

The one or more ghost signals may include a pre-ghost signal, and the feedback filter may remove a post-ghost signal from the demodulated signal based on the decision value.

The hard decision error estimator may estimate the tap coefficients of the feedforward filter and the tap coefficients of the feedback filter such that at least one of the tap coefficients of the feedforward filter overlap with at least one of the tap coefficients of the feedback filter to remove at least one of the one or more ghost signals shared by the pre-ghost signal and the post-ghost signal.

The hard decision error rate may include a first control signal to update a leaky factor of the feedforward filter and a second control signal to update a leaky factor of the feedback filter so that the tap coefficients are updated.

The leaky factors of the feedforward filter and the feedback filter vary according to the updated tap coefficients.

The foregoing and/or other aspects of the present general inventive concept may also be achieved by providing an equalization method of a digital receiver, the method including receiving and filtering a demodulated signal to remove one or more ghost signals from the demodulated signal using a feedforward filter and a feedback filter of the digital receiver, performing a subtraction operation on a first and a second filtered signal output from the feedforward filter and the feedback filter, respectively, to decide a first subtraction value, and outputting a decision value thereof, estimating a hard decision error rate according to the demodulated signal, the first filtered signal, and the decision value, and updating tap coefficients of the feedforward filter and the feedback filter, respectively, according to the hard decision error rate.

The foregoing and/or other aspects of the general inventive concept may also be achieved by providing an equalizer including first and second filters to remove pre-ghost and post-ghost signals from an input signal and output corresponding first and second filtered signals, a hard decision unit that determines whether an error is committed based on a function of the first and second filtered signals and outputs a decision value corresponding to the error determination, and a hard decision error estimator that receives an input signal, the first filtered signal and the decision value to determine an error rate of the input signal and outputs first and second control signals to the respective first and second filters to update tap coefficients of the first and second filters based on the determined error rate.

The foregoing and/or other aspects of the general inventive concept may also be achieved by providing an equalizer including first and second filters having an overlapping coverage region represented by tap coefficients corresponding to the first and second filters such that the first and second filters are capable of providing filtering capabilities to a common region of a common signal, and a hard decision error estimator that determines an error rate and provides first and second control signals to the respective first and second filters to update the tap coefficients of the first and second filters based on the determined error rate, wherein the tap coefficients are updated to allow one of the first and second filters to increase its ghost signal removing capabilities and to reduce the ghost signal removing capabilities of the other filter.

The foregoing and/or other aspects of the general inventive concept may also be achieved by providing a decision feedback channel equalizer to demodulate and equalize a signal in a digital receiver, the equalizer including a feedforward filter to receive and filter a demodulated signal to remove one or more pre-ghost signals from the demodulated signal, a first subtracter to generate a first subtraction signal based on a first signal output from the feedforward filter and a second signal, a hard decision unit to decide a decision value based on the first subtraction signal output from the first subtracter, a second subtracter to generate a second subtraction signal based on the first subtraction signal and the decision value, a feedback filter to output the second signal to the first subtracter according to the decision value, and a hard decision error estimator to estimate a hard decision error rate based on the demodulated signal, the first signal and the decision value being received, and to control the feedforward filter and the feedback filter to update tap coefficients of the feedforward filter and the feedback filter according to the hard decision error rate.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1 and 2 are schematic block diagrams of a conventional decision feedback channel equalizer;

FIG. 3 is a schematic block diagram of an equalizer usable with a VSB receiver according to an embodiment of the general inventive concept; and

FIG. 4 is a flow chart illustrating a method of a decision feedback channel equalizer according to the present general inventive concept.

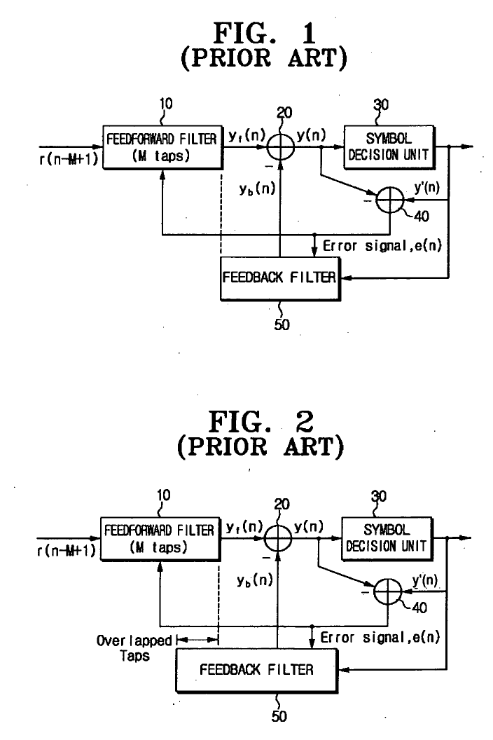

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

In the following description, like reference numerals are used to represent like elements throughout the drawings. The matters discussed in the detailed description such as a detailed construction of the embodiments and related elements are examples used to assist in a comprehensive understanding of the general inventive concept. Thus, it is apparent that the present general inventive concept can be carried out in other examples not described in the detailed description, and should not be limited the examples discussed therein. Also, well-known functions or constructions are not described in detail since they would obscure the general inventive concept in unnecessary detail.

FIG. 3 is a schematic block diagram of an equalizer 100 usable with a digital receiver according to the present general inventive concept.

As illustrated in FIG. 3, the equalizer 100 includes a feedforward filter 110, a first subtracter 120, a symbol (hard) decision unit 130, a second subtracter 140, a feedback filter 150, and a hard decision error estimator 160. An input of the equalizer 100 is connected to a demodulator (not shown), so that the equalizer receives a demodulated signal and performs equalization on the signal. Meanwhile, an output of the equalizer 100 is connected to a decoder (not shown), so that the equalized signal can be outputted to a trellis decoder (not shown).

The equalizer 100 of the present embodiment may be a decision feedback channel equalizer, which filters a pre-ghost signal through the feedforward filter 110 and removes interference from a post-ghost signal using the feedback filter 150 according to a decision value provided by the symbol decision unit 110. The equalizer 100 may also include a receiver (not shown) to receive and demodulate a modulated digital symbol signal.

The digital receiver (not shown) may be a digital broadcasting receiver such as a VSB (Vestigial Side Band) digital broadcasting receiver. Therefore, a received digital symbol signal may undergo VSB modulation, and have a multiplexed data frame structure. The equalizer 100 of the present embodiment may be used in an 8 VSB digital broadcasting receiver (not shown).

In effect, the equalizer 100 has an overlapped structure in which the feedforward filter 110 is overlapped with the feedback filter 150 similar to that of FIG. 2, and further includes the hard decision error estimator 160. This overlapping indicates that the responsibility of removing strong ghost signals is shared by the feedforward filter 110 and the feedback-filter 150, and as a result the possibility of error propagation is reduced.

A leaky LSM algorithm may be applied to each of the feedforward filter 110 and the feedback filter 150 of the equalizer 100 to update tap coefficients thereof, and the tap coefficient update Equations 3 and 4 in the Description of the Related Art may be used to determine the tap coefficients.

For simplicity, a received signal that is currently located at a main tap of the feedforward filter 110 is denoted “r(n),” an output signal from the feedforward filter 110 is denoted “y_{f}(n),” an output signal from the hard decision unit 130 is denoted “y′(n),” and an output signal of the feedback filter 150 is “y_{b}(n),” respectively.

The feedforward filter 110 is a digital filter having M taps. The feedforward filter 110 multiplies the received signal “r(n)” at each tap of the M taps by a tap coefficient, accumulates the products, and filters the received signal to remove a pre-ghost signal including noise from the received signal “r(n).”

The first subtracter 120 performs a subtract operation on the output signals “y_{f}(n)” and “y_{b}(n),” from the feedforward filter 110 and the feedback filter 150, respectively, and provides a resulting first subtraction value “y(n)” to the hard decision unit 130.

As a result, based on the first subtraction value “y(n)” from the first subtracter 120, the hard decision unit 130 decides whether an error is committed, and provides a decision value y′(n) to the second subtracter 140 and the feedback filter 150.

The second subtracter 140 performs a subtract operation on the decision value y′(n) outputted from the hard decision unit 130 and the first subtraction value “y(n)” outputted from the first subtracter 120, and provides a resulting second subtraction value or an error signal e(n), to the feedback filter 150.

By using the second subtraction value e(n), the feedback filter 150 filters the decision value y′(n) outputted from the hard decision unit 130, and removes a post-ghost signal.

The hard decision error estimator 160 receives the input signal r(n) of the equalizer 100, the output signal y_{f}(n) of the feedforward filter 110, and the output signal y′(n) of the hard decision unit 130, and estimates a hard decision error rate therefrom. Further, based on this estimated value, the hard decision error estimator 160 transmits a first control signal to update a leaky factor of the feedforward filter 110, and a second control signal to update a leaky factor of the feedback filter 150, respectively, thereby allowing the control signals to be reflected in the tap coefficient update equations.

The following will now explain a hard decision error rate estimation algorithm applied to the hard decision error estimator 160.

In general, the received signal r(n) includes a signal component that the equalizer 100 intends to output at the end after performing equalization. Therefore, if no hard decision error is committed, the value of |r(n)−y′(n)|ⁿ or |y_{f}(n)−y′(n)|ⁿ will probably be smaller than a regular value associated with a hard decision error. Here, ‘n’ may indicate a random positive integer. This is because a properly given hard decision value having no error offsets the same signal component included in the received signal.

That is, if the hard decision error is not committed, the values of E|r(n)−y′(n)|ⁿ and E|y_{f}(n)−y′(n)|ⁿ are small, whereas the values of E{r(n)y′*(n)} and E{y_{f}(n)y′*(n)} are large.

On the other hand, if the hard decision error is committed, the values of E|r(n)−y′(n)|ⁿ and E|y_{f}(n)−y′(n)|ⁿ are large, whereas the values of E{r(n)y′*(n)} and E{y_{f}(n)y′*(n)} are small.

Therefore, based on the values of E|r(n)−y′(n)|ⁿ, E|y_{f}(n)−y′(n)|ⁿ, E{r(n)y′*(n)}, and E{y_{f}(n)y′*(n)} (hereinafter referred to as matrix values), it becomes possible to investigate whether an error propagation problem occurred. If the error propagation problem was found to have occurred, the tap coefficient updates of the feedforward filter 110 and the feedback filter 150 may be adaptively controlled based on the error propagation problem.

Using an error rate status estimated by the hard decision error estimator 160, the tap coefficients of the feedforward filter 110 and the feedback filter 120 can be updated through Equations 5 and 6 below.
W_{f}(n+1)=[1−Γ_{f}(μ_{f}·β_{f}(r(n),y_{f}(n),y′(n)))]W_{f}(n)+μ_{f}r(n)e*(n) [Equation 5]
where Γ_{f}(μ_{f}·β_{f}(r(n),y_{f}(n),y′(n))) is a leaky factor of the feedforward filter 110 and is either a monotone increasing function or a monotone decreasing function having a value between 0 and 1.

Also, β_{f}(r(n),y_{f}(n),y′(n)) is expressed by one of the matrix values, i.e., β_{f}(r(n),y_{f}(n),y′(n))=K_{f}·E|y_{f}(n)y′*(n)|. Here, K_{f} is a random positive real number determined by the E|y_{f}(n)y′*(n)| value. And, Γ_{f} function value is set to increase monotonely.

Referring to Equation 5, in a situation where the decision error rate is low, the leaky factor increases and the ghost signal removing capabilities of the feedforward filter 110 are limited. However, the opposite result is obtained in a situation where the decision error rate is high.
W_{b}(n+1)=[1−Γ_{b}(μ_{b}·β_{b}(r(n),y_{f}(n),y′(n)))]W_{b}(n)+μ_{b}r(n)e*(n) [Equation 6]
where Γ_{b}(μ_{b}·β_{b}(r(n),y_{f}(n),y′(n))) is a leaky factor of the feedback filter 150, and is either a monotone increasing function or a monotone decreasing function having a value between 0 and 1.

Also, β_{b}(r(n),y_{f}(n),y′(n)) is expressed by one of the matrix values, i.e., β_{b}(r(n),y_{f}(n),y′(n))=K_{b}·E|y_{f}(n)y′*(n)|ⁿ. Here, K_{b} is a random positive real number determined by the E|y_{f}(n)y′*(n)|ⁿ value. And, Γ_{b} function value is set to decrease monotonely.

Referring to Equation 6, in a situation where the decision error rate is high, the leaky factor increases and the ghost signal removing capabilities of the feedback filter 150 are limited. However, the opposite result is obtained in a situation where the decision error rate is low.

Therefore, the leaky factor of the feedforward filter 110 and the leaky factor of the feedback filter 150 are adjusted according to the decision error rate. For instance, if the decision error rate is high, the leaky factor of the feedforward filter 110 is decreased and the leaky factor of the feedback filter 150 is increased, so that the ghost signal removing capabilities of the feedforward filter 110 are limited and the feedback filter 150 is mainly used to remove ghost signals. In contrast, if the decision error rate is low, the leaky factor of the feedforward filter 110 is decreased and the leaky factor of the feedback filter 150 is increased, so that the ghost signal removing capabilities of the feedback filter 150 are limited and the feedforward filter 110 is mainly used to remove ghost signals.

The decision feedback channel equalizer 100 of the present embodiment can be used to obtain an optimum error rate because the decision feedback channel equalizer 100 estimates the error rate of the hard decision unit 130 and adaptively adjusts the leaky factors of the feedforward filter 110 and the feedback filter 150 based on the estimated error rate. Moreover, the decision feedback channel equalizer 100 can be used to automatically find a system parameter by channels, so it can be readily used in real life.

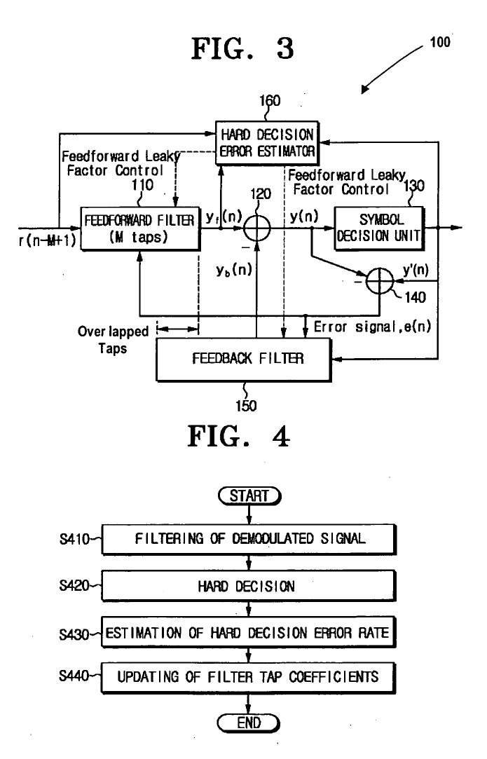

FIG. 4 is a flow chart illustrating a method of a decision feedback channel equalizer usable with a digital receiver according to an embodiment of the present general inventive concept.

Referring to FIGS. 3 and 4, the decision feedback channel equalizer 100 receives a demodulated signal from a demodulator (not shown), and filters the received signal by means of the feedforward filter 110 and the feedback filter 150 (operation S410).

The hard decision unit 130 performs a hard decision of the signal by using the signal values outputted from the feedforward filter 110 and the feedback filter 150, respectively, and outputs a decision value (operation S420).

The hard decision error estimator 160 estimates a hard decision error (rate) based on the demodulated input signal to the feedforward filter 110, the output signal of the feedforward filter 110, and the decision value outputted from the hard decision unit 130 (operation S430).

Depending on the estimation result from the hard decision error estimator 160 regarding whether or not the error has occurred, the equalizer adaptively controls the feedforward filter 110 and the feedback filter 150, and updates the tap coefficients of the feedforward filter 110 and the feedback filter 150 by applying the Equations 5 and 6 thereto, respectively (operation S440).

That is, if the error rate is low, the ghost signal removing capabilities of the feedforward filter 110 are limited. To this end, in Equation 5, the tap coefficient of the feedforward filter 110 is updated by increasing the leaky factor thereof. Thus, channel equalization is performed by allowing the feedback filter 150 to focus on ghost signal removing more than the feedforward filter 110. In contrast, if the error rate is high due to error propagation, the ghost signal removing capabilities of the feedback filter 150 must be limited. To this end, in Equation 6, the tap coefficient of the feedback filter 150 is updated by increasing the leaky factor thereof. Thus, channel equalization is performed by allowing the feedforward filter 110 to focus on ghost signal removing more so than the feedback filter 150.

As explained so far, according to the present general inventive concept, the tap coefficients of the feedforward filter 110 and the feedback filter 150 are adjusted adaptively based on the hard decision error rate. In this manner, the feedback filter 150 can keep its ghost signal removing capabilities as much as possible, while suppressing the error propagation at the same time.

Therefore, the output SNR of the equalizer 100 can be maintained in its optimal status, and the filter tap coefficients can be automatically updated when changes occur in corresponding channel environments.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A decision feedback channel equalizer to demodulate and equalize a signal in a digital receiver, the equalizer comprising:
a feedforward filter to receive and filter a demodulated signal to remove one or more ghost signals from the demodulated signal;
a hard decision unit to decide a decision value based on a first signal output from the feedforward filter;
a feedback filter to receive and filter the decision value, and to output a second signal; and
a hard decision error estimator to estimate a hard decision error rate based on the demodulated signal, the first signal and the decision value being received, and to control the feedforward filter and the feedback filter to update tap coefficients of the feedforward filter and the feedback filter according to the hard decision error rate.

2. The decision feedback channel equalizer according to claim 1, wherein, if the error rate estimated by the hard decision error estimator is low, the hard decision error estimator updates the tap coefficient of the feedforward filter to limit ghost signal removing capabilities of the feedforward filter.

3. The decision feedback channel equalizer according to claim 1, wherein, if the error rate estimated by the hard decision error estimator is high, the hard decision error estimator updates the tap coefficient of the feedback filter to limit ghost signal removing capabilities of the feedback filter.

4. The decision feedback channel equalizer according to claim 1, wherein the hard decision error estimator updates the tap coefficient of the feedforward filter by applying the following equation:
W_{f}(n+1)=[1−Γ_{f}(μ_{f}·β_{f}(r(n),y_{f}(n),y′(n)))]W_{f}(n)+μ_{f}r(n)e*(n)
where “Γ_{f}(μ_{f}·β_{f}(r(n),y_{f}(n),y′(n)))” is a feedforward leaky factor, having a value in a range from 0 to 1, “W_{f}(n),” “r(n)” and “μ_{f}” indicate a tap coefficient vector, demodulated signal vector, and step size of a feedforward filter, respectively, and “e*(n)” indicates an error signal.

5. The decision feedback channel equalizer according to claim 4, wherein the feedforward leaky factor of the feedforward filter is calculated by the following equation:
Γ_{f}(μ_{f}·β_{f}(r(n),y_{f}(n),y′(n)))=Γ_{f}(μ_{f}·K_{f}·E{y_{f}(n)y′*(n)})
where “K_{f}” is a random positive real number.

6. The decision feedback channel equalizer according to claim 1, wherein the hard decision error estimator updates the tap coefficient of the feedback filter by applying the following equation:
W_{b}(n+1)=[1−Γ_{b}(μ_{b}·β_{b}(r(n),y_{f}(n),y′(n)))]W_{b}(n)+μ_{b}r(n)e*(n)
where “Γ_{b}(μ_{b}·β_{b}(r(n),y_{f}(n),y′(n)))” is a feedback leaky factor, having a value in a range from 0 to 1; “W_{b}(n),” “r(n)” and “μ_{b}” indicate a tap coefficient vector, demodulated signal vector, and step size of a feedback filter, respectively; and “e*(n)” indicates an error signal.

7. The decision feedback channel equalizer according to claim 6, wherein the feedback leaky factor of the feedback filter is calculated by the following equation:
Γ_{b}(μ_{b}·β_{b}(r(n),y_{f}(n),y′(n)))=Γ_{b}(μ_{b}·K_{b}·E|y_{f}(n)−y′(n)|ⁿ)
where “K_{b}” is a random positive real number.

8. The decision feedback channel equalizer according to claim 1, wherein the hard decision error estimator uses at least one of E|r(n)−y′(n)|ⁿ, E{r(n)y′*(n)}, E|y_{f}(n)−y′(n)|ⁿ, and E{y_{f}(n)y′*(n)} values to estimate the hard decision error rate, when “r(n),” “y_{f}(n)” and “y′(n)” indicate the demodulated input signal, the first signal and the decision value, respectively.

9. The decision feedback channel equalizer according to claim 1, further comprising:
a first subtracter to perform a first subtraction operation on the first and the second signals received from the feedforward filter and the feedback filter, respectively, and to calculate a first subtraction value from the first subtraction operation.

10. The decision feedback channel equalizer according to claim 9, further comprising:
a second subtracter to perform a second subtraction operation by subtracting the first subtraction value received from the first subtracter and the decision value received from the hard decision unit to generate a second subtraction value from the second subtraction operation, and to provide the generated second subtraction value to the feedback filter to output the second signal.

11. The decision feedback channel equalizer according to claim 1, wherein the one or more ghost signals are a pre-ghost signal, and the feedback filter removes a post-ghost signal from the demodulated signal based on the decision value.

12. The decision feedback channel equalizer according to claim 11, wherein the hard decision error estimator estimates the tap coefficients of the feedforward filter and the tap coefficients of the feedback filter such that at least one of the tap coefficients of the feedforward filter overlap with at least one of the tap coefficients of the feedback filter to remove at least one of the one or more ghost signals shared by the pre-ghost signal and the post-ghost signal.

13. The decision feedback channel equalizer according to claim 1, wherein the hard decision error rate comprises a first control signal to update a leaky factor of the feedforward filter and a second control signal to update a leaky factor of the feedback filter so that the tap coefficients are updated.

14. The decision feedback channel equalizer according to claim 13, wherein the leaky factors of the feedforward filter and the feedback filter vary according to the updated tap coefficients.

15. An equalization method of a digital receiver, the method comprising:
receiving and filtering a demodulated signal to remove one or more ghost signals from the demodulated signal using a feedforward filter and a feedback filter of the digital receiver;
performing a subtraction operation on a first and a second filtered signal ouput from the feedforward filter and the feedback filter, respectively, to decide a first subtraction value, and outputting a decision value thereof;
estimating a hard decision error rate according to the demodulated signal, the first filtered signal, and the decision value; and
updating tap coefficients of the feedforward filter and the feedback filter, respectively, according to the hard decision error rate.

16. The method according to claim 11, wherein the updating of the tap coefficients of the feedforward filter and the feedback filter, respectively, according to the hard decision error rate comprises if the estimated error rate is low, updating the tap coefficient of the feedforward filter so as to limit a ghost signal removing capability of the feedforward filter.

17. The method according to claim 11, wherein the updating of the tap coefficients of the feedforward filter and the feedback filter, respectively, according to the hard decision error rate comprises if the estimated error rate is high, updating the tap coefficient of the feedback filter so as to limit ghost signal removing capabilities of the feedback filter.

18. The method according to claim 11, wherein the coefficient update of the feedforward filter is performed by applying the following equation:
W_{f}(n+1)=[1−Γ_{f}(μ_{f}·β_{f}(r(n),y_{f}(n),y′(n)))]W_{f}(n)+μ_{f}r(n)e*(n)
where “Γ_{f}(μ_{f}·β_{f}(r(n),y_{f}(n),y′(n)))” is a feedforward leaky factor, having a value in a range from 0 to 1, “W_{f}(n),” “r(n)” and “μ_{f}” indicate a tap coefficient vector, demodulated signal vector, and step size of a feedforward filter, respectively, and “e*(n)” indicates an error signal.

19. The method according to claim 14, wherein the leaky factor of the feedforward filter is calculated by the following equation:
Γ_{f}(μ_{f}·β_{f}(r(n),y_{f}(n),y′(n)))=Γ_{f}(μ_{f}·K_{f}·E{y_{f}(n)y′*(n)})
where “K_{f}” is a random positive real number.

20. The method according to claim 11, wherein the tap coefficient update of the feedback filter is performed by applying the following equation:
W_{b}(n+1)=[1−Γ_{b}(μ_{b}·β_{b}(r(n),y_{f}(n),y′(n)))]W_{b}(n)+μ_{b}r(n)e*(n)
where “Γ_{b}(μ_{b}·β_{b}(r(n),y_{f}(n),y′(n)))” is a feedback leaky factor, having a value in a range from 0 to 1, “W_{b}(n),” “r(n)” and “μ_{b}” indicate a tap coefficient vector, demodulated signal vector, and step size of a feedback filter, respectively; and “e*(n)” indicates an error signal.

21. The method according to claim 16, wherein the leaky factor of the feedback filter is calculated by the following equation:
Γ_{b}(μ_{b}·β_{b}(r(n),y_{f}(n),y′(n)))=Γ_{b}(μ_{b}·K_{b}·E|y_{f}(n)−y′(n)|ⁿ)
where “K_{b}” is a random positive real number.

22. The method according to claim 11, wherein the hard decision error rate is estimated using at least one of E|r(n)−y′(n)|ⁿ, E{r(n)y′*(n)}, E|y_{f}(n)−y′(n)|ⁿ, and E{y_{f}(n)y′*(n)} values to estimate the hard decision error rate, where “r(n),” “y_{f}(n)” and “y′(n)” indicate the demodulated input signal, the first signal and the decision value, respectively.

23. An equalizer comprising:
first and second filters to remove pre-ghost and post-ghost signals from an input signal and output corresponding first and second filtered signals;
a hard decision unit that determines whether an error is committed based on a function of the first and second filtered signals and outputs a decision value corresponding to the error determination; and
a hard decision error estimator that receives the input signal, the first filtered signal and the decision value to determine an error rate of the input signal and outputs first and second control signals to the respective first and second filters to update tap coefficients of the first and second filters based on the determined error rate.

24. The equalizer of claim 19, wherein the function is defined as a difference of the first and second filtered signals.

25. The equalizer of claim 19, wherein the control signals update leaky factors of the first and second filters according to a LMS algorithm, the leaky factors are inversely proportional to the tap coefficients, and the leaky factors are adjusted based on the error rate.

26. The equalizer of claim 19, wherein the tap coefficients of the first and second filters are updated automatically depending on changes in a channel environment of the input signal.

27. An equalizer comprising:
first and second filters having an overlapping coverage region represented by tap coefficients corresponding to the first and second filters such that the first and second filters are capable of providing filtering capabilities to a common region of a common signal; and
a hard decision error estimator that determines an error rate and provides first and second control signals to the respective first and second filters to update the tap coefficients of the first and second filters based on the determined error rate, wherein the tap coefficients are updated to allow one of the first and second filters to increase its ghost signal removing capabilities and to reduce the ghost signal removing capabilities of the other filter.

28. A decision feedback channel equalizer to demodulate and equalize a signal in a digital receiver, the equalizer comprising:
a feedforward filter to receive and filter a demodulated signal to remove one or more pre-ghost signals from the demodulated signal;
a first subtracter to generate a first subtraction signal based on a first signal output from the feedforward filter and a second signal;
a hard decision unit to decide a decision value based on the first subtraction signal output from the first subtracter;
a second subtracter to generate a second subtraction signal based on the first subtraction signal and the decision value;
a feedback filter to output the second signal to the first subtracter according to the decision value; and
a hard decision error estimator to estimate a hard decision error rate based on the demodulated signal, the first signal and the decision value being received, and to control the feedforward filter and the feedback filter to update tap coefficients of the feedforward filter and the feedback filter according to the hard decision error rate.
